(19) United States
(12) Patent Application Publication
(10) Pub. No.: US 2021/0367202 A1
(43) Pub. Date: Nov. 25, 2021

(54) DISPLAY PANEL AND DISPLAY SCREEN HAVING SAME

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xiaoliang FENG, Wuhan, Hubei (CN)

(21) Appl. No.: 16/472,072

(22) PCT Filed: Feb. 13, 2019
(86) PCT No.: PCT/CN2019/074899

§ 371 Date: Jun. 20, 2019

(30) Foreign Application Priority Data
Dec. 19, 2018 (CN) 201811552452.5

(51) Int. Cl. H01L 51/52; H01L 27/32; H01L 51/50

(52) U.S. Cl. CPC H01L 51/5253; H01L 27/3276; H01L 51/5092; H01L 51/5072; H01L 51/5056

(57) ABSTRACT

The present disclosure provides a display panel and a display screen having the same. The display panel comprises a first insulating layer; a transparent electrode layer; a first metal layer comprising a first region and a second region that the first region is formed on the transparent electrode layer and has an opening; a second insulating layer covering the first region, the second region, and the first insulating layer so that a first through via and a second through via are commonly formed by the second insulating layer and the first insulating layer, and the second insulating layer forms a third through via on the first region of the first metal layer; a luminous layer located within the opening; a cathode layer connected to the luminous layer through the opening; and a second encapsulation layer formed on the cathode layer.

### FIELD OF INVENTION

The present invention relates to a display panel, and more particularly to a display panel having double-sided encapsulation layer and a display screen having the display panel.

### BACKGROUND OF INVENTION

Currently, packaging of an OLED display screen is a major limiting factor in lifespan of an OLED device. Generally, the encapsulation layer, consisting of SiNₓ and a thin film encapsulation (TFE) layer, is formed on a cathode to ensure isolation of water and oxygen, and has a flexibility function, e.g. the OLED packaging technology described in U.S. Pat. Nos. 9,692,010 and 9,419,247. However, in actual production, the yield of the above packaging technology is relatively low, and reliability of the product may have certain risks.

It is therefore necessary to provide a display panel and a display screen thereof, in order to solve the technical problems existing in the conventional technology as described above.

### SUMMARY OF INVENTION

The primary object of the present invention is to provide a display panel and a display screen thereof, which can effectively protect an organic light emitting diode within its structure. The display panel has two layers of encapsulation layers, which can more effectively insulate water and/or oxygen from intrusion. Furthermore, in the display panel, there is no opaque metal line, such as the cathode, in the main light emitting direction of the organic light emitting diode, and thus the transmittance of the whole structure can be improved, and the brightness can be improved, too.

To achieve above objects, one embodiment of the present invention provides a display panel, comprising a first encapsulation layer; a first buffer layer formed on the first encapsulation layer; an active layer formed on the first buffer layer; a first insulating layer covering the active layer and the first buffer layer; a transparent electrode layer formed on the first insulating layer to be an anode; a first metal layer comprising a first region and a second region, wherein the first region is formed on the transparent electrode layer and has an opening, and the second region is formed on a position corresponding to the active layer over the first insulating layer to be a gate electrode; a second insulating layer covering the first region, the second region, and the first insulating layer, wherein the second insulating layer and the first insulating layer on the active layer commonly form a first through via and a second through via, and the second insulating layer forms a third through via on the first region of the first metal layer; a second metal layer formed on the second insulating layer, connected to the active layer through the first through via and the second through via, and connected to the first region of the first metal layer through the third through via; a pixel layer covering the second insulating layer and the second metal layer, and connected to the anode through the opening; a luminous layer located within the opening; a cathode layer connected to the luminous layer through the opening; a second encapsulation layer formed on the cathode layer; a second buffer layer formed on the second encapsulation layer; and a flexible transparent layer formed on the second buffer layer.

In one embodiment of the present invention, the active layer comprises an n-type polysilicon and a p-type polysilicon, and the n-type polysilicon and the p-type polysilicon respectively corresponds to the first through via and the second through via, wherein the n-type polysilicon and the p-type polysilicon form a source electrode and a drain electrode, respectively.

In one embodiment of the present invention, both of the first encapsulation layer and the second encapsulation layer are thin film encapsulation layers.

In one embodiment of the present invention, the second metal layer comprises data lines, a source electrode, and a drain electrode.

In one embodiment of the present invention, each of the first buffer layer and the second buffer layer is silicon nitride, silica, or silicon oxynitride.

In one embodiment of the present invention, the second encapsulation layer has a multilayer structure consisting of at least one silicon nitride and at least one thin film encapsulation layer which are stacked each other.

Another embodiment of the present invention provides a display panel, comprising a first encapsulation layer; a first buffer layer formed on the first encapsulation layer; an active layer formed on the first buffer layer; a first insulating layer covering the active layer and the first buffer layer; a transparent electrode layer formed on the first insulating layer to be an anode; a first metal layer comprising a first region and a second region, wherein the first region is formed on the transparent electrode layer and has an opening, and the second region is formed on a position corresponding to the active layer over the first insulating layer to be a gate electrode; a luminous layer located within the opening; a cathode layer covering the pixel layer and connected to the luminous layer through the opening; and a second encapsulation layer formed on the cathode layer.

In one embodiment of the present invention, the active layer comprises an n-type polysilicon and a p-type polysilicon, and the n-type polysilicon and the p-type polysilicon respectively corresponds to the first through via and the second through via.

In one embodiment of the present invention, the n-type polysilicon and the p-type polysilicon form a source electrode and a drain electrode, respectively.

In one embodiment of the present invention, both of the first encapsulation layer and the second encapsulation layer are thin film encapsulation layers.

In one embodiment of the present invention, the display panel further comprises a second insulating layer covering the first region, the second region, and the first insulating layer, wherein the second insulating layer and the first insulating layer on the active layer commonly form a first through via and a second through via, and the second insulating layer forms a third through via on the first region of the first metal layer; a second metal layer formed on the second insulating layer, connected to the active layer through the first through via and the second through via, and connected to the first region of the first metal layer through the third through via; and a pixel layer covering the second insulating layer and the second metal layer, and connected to the anode through the opening.

In one embodiment of the present invention, the second metal layer comprises data lines, a source electrode, and a drain electrode.

In one embodiment of the present invention, a silicon nitride layer is provided between the first buffer layer and the first encapsulation layer.

In one embodiment of the present invention, the display panel further comprises a second buffer layer formed on the second encapsulation layer, and a flexible transparent layer formed on the second buffer layer.

In one embodiment of the present invention, each of the first buffer layer and the second buffer layer is silicon nitride (SiNₓ), silica (SiOₓ), or silicon oxynitride (SiNO).

In one embodiment of the present invention, the luminous layer includes a hole injection layer, a hole transport layer, an electron barrier layer, a luminescent material layer, a hole barrier layer, an electron transport layer, and an electron injection layer.

In one embodiment of the present invention, the flexible transparent layer is polyimide.

In one embodiment of the present invention, the second encapsulation layer has a multilayer structure consisting of at least one silicon nitride and at least one thin film encapsulation layer which are stacked each other.

A further embodiment of the present invention provides a display screen, wherein the display screen comprises the abovementioned display panel, wherein the luminous layer emits a light passing through the transparent electrode layer.

### BRIEF DESCRIPTION OF DRAWINGS

FIGS. 1A-1F show a manufacturing flow of a display panel according to the present invention.

FIG. 2 is a schematic view for showing a direction of a light exiting a display panel applied to a display screen according to the present invention.

### DETAILED DESCRIPTION OF PREFERRED EMBODIMENTS

The detailed description of the following embodiments is used for exemplifying the specific embodiments of the present invention by referring to the accompany drawings. Furthermore, directional terms described by the present invention, such as upper, lower, front, back, left, right, inner, outer, side, etc., are only directions by referring to the accompanying drawings, and thus the directional terms are used to describe and understand the present invention, but the present invention is not limited thereto.

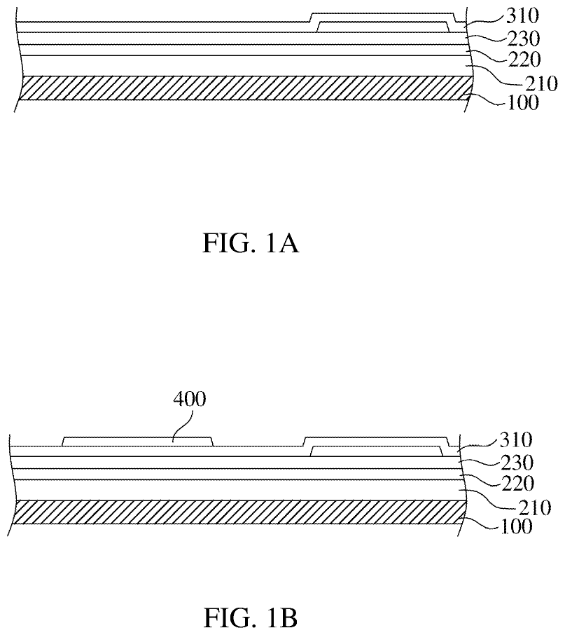

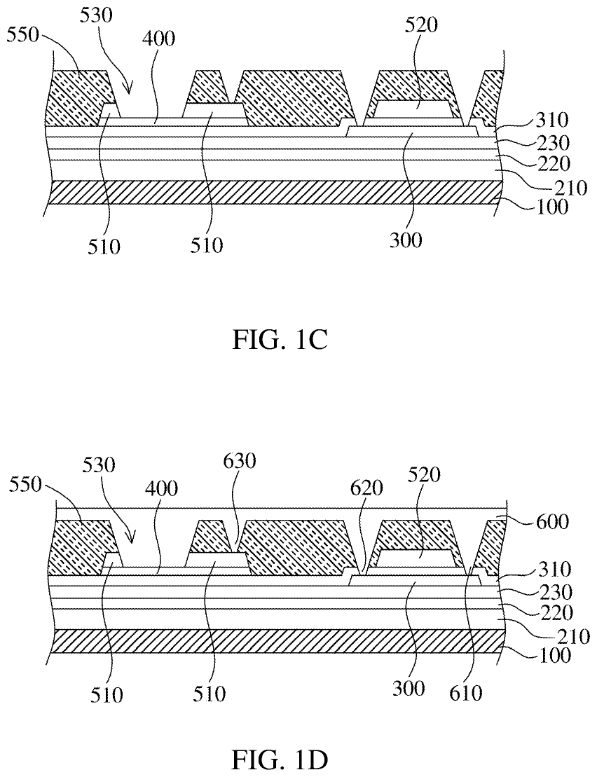

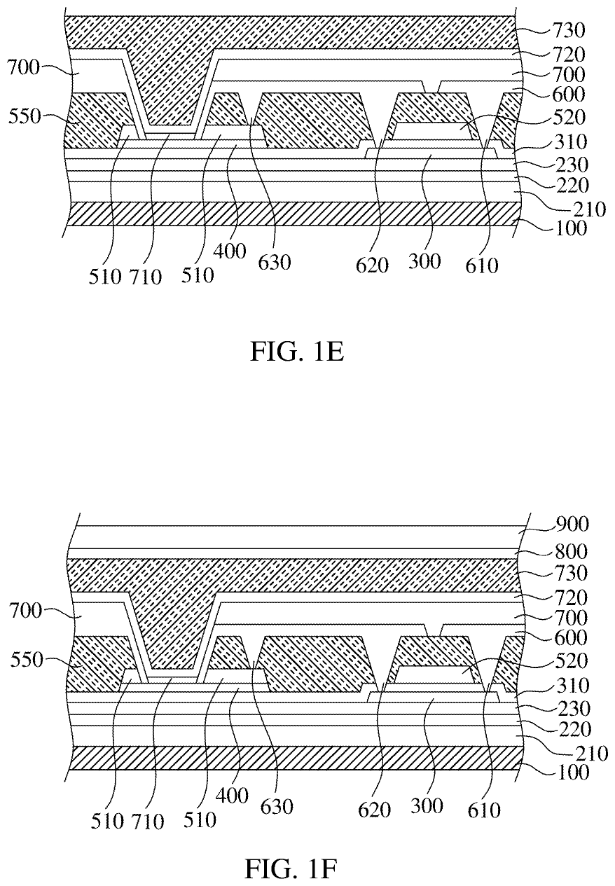

Referring to FIGS. 1A to 1F, which show a brief flow of forming a display panel of the present invention. As shown in FIG. 1A, a first encapsulation layer 210, a silicon nitride layer 220, and a first buffer layer 230 are sequentially produced on a substrate 100. The first buffer layer 230 can be formed by silicon nitride (SiNₓ), silica (SiOₓ), or silicon oxynitride (SiNO), but the material is not limited thereto. Next, an active layer 300 is formed on the first buffer layer 230. The active layer can form polysilicon by a crystallization step, and form an n-type polysilicon and a p-type polysilicon by doping. The first encapsulation layer 210 can be a thin film encapsulation layer. The thin film encapsulation layer is referred to a multilayer structure comprising organic materials and inorganic materials which are stacked each other.

As shown in FIG. 1B, a first insulating layer 310 is formed on the active layer 300 to cover the active layer 300 and the first buffer layer 230. The material of the first insulating layer 310 can be SiNₓ and hole positions can be reserved at positions of the n-type polysilicon and the p-type polysilicon. Alternatively, it is also possible to perform a suitable treatment, such as etching, to form a contact hole connected with the active layer. Next, a transparent electrode layer 400 is formed on the first insulating layer 310, and the transparent electrode layer 400 is formed on an area out of the active layer 300, for example, the position at left side of FIG. 1B. The transparent electrode layer 400 can be an indium tin oxide (ITO) layer served as an anode.

Please refer to FIG. 1C, a first metal layer is formed subsequently. The first metal layer comprises a first region 510 and a second region 520. The first region 510 is located on the transparent electrode layer 400 and has an opening 530. The second region 520 is formed on a position corresponding to the active layer 300 over the first insulating layer 310 to be a gate electrode. Next, a second insulating layer 550 covers the first region 510, the second region 520, and the first insulating layer 310, wherein the second insulating layer 550 and the first insulating layer 310 commonly form a first through via 620 and a second through via 630 on the active layer 300, and the second insulating layer 550 forms a third through via 630 on the first region 510 of the first metal layer.

Refer to FIG. 1D, a second metal layer 600 is formed on the second insulating layer 550, and connected to the n-type polysilicon and the p-type polysilicon of the active layer 300 through the first through via and the second through via to form a source electrode (at the first through via 610) and a drain electrode (at the second through via 620), and also connected to the first region 510 of the first metal layer on the transparent electrode layer 400 through the third through via 630. The second metal layer 600 also comprises several data lines.

Refer to FIG. 1E, a pixel layer 700 is formed to cover the second insulating layer 550 and the second metal layer 600, and connected to the transparent electrode layer 400 (i.e. the anode) through the opening 530. Also, the opening 530 above the transparent electrode layer 400 forms a space for placing a luminous layer. Next, a luminous layer 710 is provided with a multilayer structure, such as the general structure of the luminous layer including a hole injection layer, a hole transport layer, an electron barrier layer, a luminescent material layer, a hole barrier layer, an electron transport layer, and an electron injection layer, but it is not limited thereto.

Subsequently, a cathode layer 720 and a second encapsulation layer 730 are produced. The second encapsulation layer 730 can be a thin film encapsulation layer or a multilayer structure including several thin film encapsulating layers. For example, the multilayer structure consists of at least one silicon nitride and at least one thin film encapsulation layer which are stacked each other.

Next, as shown in FIG. 1F, a second buffer layer 800 is formed on the second encapsulation layer 730. The material of the second buffer layer 800 can be similar with the material of the first buffer layer 230 that can be silicon nitride (SiNₓ), silica (SiOₓ), or silicon oxynitride (SiNO), but it is not limited thereto. The first buffer layer 230 and the second buffer layer 800 can use same or different materials. Next, a flexible transparent layer 900 is formed on the second buffer layer. The flexible transparent layer 900 can be polyimide (PI), but it is not limited thereto. Any flexible material with high transmittance can be used as a base layer of a flexible light emitting diode (OLED).

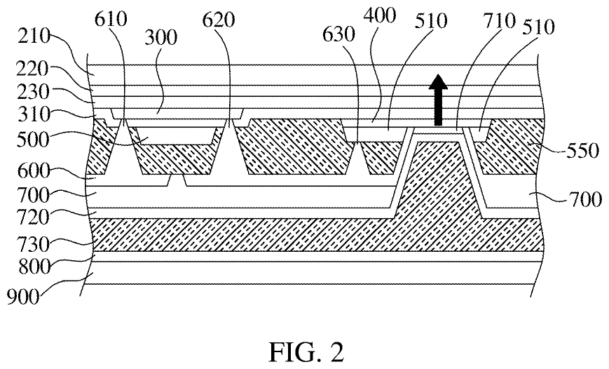

Finally, as long as the substrate 100 is peeled off by using laser lift off, a flexible OLED display screen as shown in FIG. 2 can be produced.

FIG. 2 is a schematic view for showing the actual light output of the display panel according to the above embodiment. The direction of FIG. 2 is opposite to the direction of FIG. 1F. The upper side of FIG. 2 shows a visible surface. From the visible surface, users can watch the display effects of the display screen, so that the light of the OLED is emitted through the transparent electrode layer 400 and then enters the eyes of the users. Compared with the cathode layer 720, the transparent electrode layer 400 has a higher transmittance so that the brightness of the OLED display screen is also improved.

Compared with the prior art, the display panel of the present invention has two layers of encapsulation layers, which can more effectively insulate water and/or oxygen from intrusion. Furthermore, in the display panel, there is no opaque metal line, such as the cathode, in the main light emitting direction of the organic light emitting diode, and thus the transmittance of the whole structure can be improved, and the brightness can be improved, too.

The present application has been described by the above related embodiments, but the above embodiments are merely examples for implementing the present application. It must be noted that the disclosed embodiments do not limit the scope of the present application. Rather, modifications and equivalent arrangements included in the spirit and scope of the claims are intended to be included within the scope of the present application.

What is claimed is:

1. A display panel, comprising:
a first encapsulation layer;
a first buffer layer formed on the first encapsulation layer;
an active layer formed on the first buffer layer;
a first insulating layer covering the active layer and the first buffer layer;
a transparent electrode layer formed on the first insulating layer to be an anode;
a first metal layer comprising a first region and a second region, wherein the first region is formed on the transparent electrode layer and has an opening, and the second region is formed on a position corresponding to the active layer over the first insulating layer to be a gate electrode;
a second insulating layer covering the first region, the second region, and the first insulating layer, wherein the second insulating layer and the first insulating layer on the active layer commonly form a first through via and a second through via, and the second insulating layer forms a third through via on the first region of the first metal layer;
a second metal layer formed on the second insulating layer, connected to the active layer through the first through via and the second through via, and connected to the first region of the first metal layer through the third through via;
a pixel layer covering the second insulating layer and the second metal layer, and connected to the anode through the opening;
a luminous layer located within the opening;
a cathode layer connected to the luminous layer through the opening;
a second encapsulation layer formed on the cathode layer;
a second buffer layer formed on the second encapsulation layer; and
a flexible transparent layer formed on the second buffer layer.

2. The display panel according to claim 1, wherein the active layer comprises an n-type polysilicon and a p-type polysilicon, and the n-type polysilicon and the p-type polysilicon respectively corresponds to the first through via and the second through via, wherein the n-type polysilicon and the p-type polysilicon form a source electrode and a drain electrode, respectively.

3. The display panel according to claim 1, wherein both of the first encapsulation layer and the second encapsulation layer are thin film encapsulation layers.

4. The display panel according to claim 1, wherein the second metal layer comprises data lines, a source electrode, and a drain electrode.

5. The display panel according to claim 1, wherein each of the first buffer layer and the second buffer layer is silicon nitride, silica, or silicon oxynitride.

6. The display panel according to claim 1, wherein the second encapsulation layer has a multilayer structure consisting of at least one silicon nitride and at least one thin film encapsulation layer which are stacked each other.

7. A display panel, comprising:
a first encapsulation layer;
a first buffer layer formed on the first encapsulation layer;
an active layer formed on the first buffer layer;
a first insulating layer covering the active layer and the first buffer layer;
a transparent electrode layer formed on the first insulating layer to be an anode;
a first metal layer comprising a first region and a second region, wherein the first region is formed on the transparent electrode layer and has an opening, and the second region is formed on a position corresponding to the active layer over the first insulating layer to be a gate electrode;
a luminous layer located within the opening;
a cathode layer connected to the luminous layer through the opening; and
a second encapsulation layer formed on the cathode layer.

8. The display panel according to claim 7, wherein the active layer comprises an n-type polysilicon and a p-type polysilicon, and the n-type polysilicon and the p-type polysilicon respectively corresponds to the first through via and the second through via.

9. The display panel according to claim 8, wherein the n-type polysilicon and the p-type polysilicon form a source electrode and a drain electrode, respectively.

10. The display panel according to claim 7, wherein both of the first encapsulation layer and the second encapsulation layer are thin film encapsulation layers.

11. The display panel according to claim 7, wherein the display panel further comprises:
a second insulating layer covering the first region, the second region, and the first insulating layer, wherein the second insulating layer and the first insulating layer on the active layer commonly form a first through via and a second through via, and the second insulating layer forms a third through via on the first region of the first metal layer;
a second metal layer formed on the second insulating layer, connected to the active layer through the first through via and the second through via, and connected to the first region of the first metal layer through the third through via; and
a pixel layer covering the second insulating layer and the second metal layer, and connected to the anode through the opening.

12. The display panel according to claim 11, wherein the second metal layer comprises data lines, a source electrode, and a drain electrode.

13. The display panel according to claim 7, wherein a silicon nitride layer is provided between the first buffer layer and the first encapsulation layer.

14. The display panel according to claim 7, wherein the display panel further comprises a second buffer layer formed on the second encapsulation layer, and a flexible transparent layer formed on the second buffer layer.

15. The display panel according to claim 14, wherein each of the first buffer layer and the second buffer layer is silicon nitride, silica, or silicon oxynitride.

16. The display panel according to claim 7, wherein the luminous layer includes a hole injection layer, a hole transport layer, an electron barrier layer, a luminescent material layer, a hole barrier layer, an electron transport layer, and an electron injection layer.

17. The display panel according to claim 7, wherein the flexible transparent layer is polyimide.

18. The display panel according to claim 7, wherein the second encapsulation layer has a multilayer structure consisting of at least one silicon nitride and at least one thin film encapsulation layer which are stacked each other.

19. A display screen, comprising a display panel according to claim 7, wherein the luminous layer emits a light passing through the transparent electrode layer.
